(19) United States
(12) Patent Application Publication
(10) Pub. No.: US 2026/0169032 A1
(43) Pub. Date: Jun. 18, 2026

(54) SEMICONDUCTOR TESTING APPARATUS AND SEMICONDUCTOR TESTING METHOD

(71) Applicant: Taiwan Semiconductor Manufacturing Company, Ltd., Hsinchu (TW)

(72) Inventors: Mill-Jer Wang, Hsinchu (TW); Pei-Ching Lin, Hsinchu (TW); Kam Heng Lee, Hsinchu City (TW)

(73) Assignee: Taiwan Semiconductor Manufacturing Company, Ltd., Hsinchu (TW)

(21) Appl. No.: 18/983,394

(22) Filed: Dec. 17, 2024

(51) Int. Cl. G01R 1/073; G01R 1/067; G01R 31/28

(52) U.S. Cl. CPC G01R 1/07342; G01R 1/06722; G01R 31/2886

(57) ABSTRACT

A semiconductor testing apparatus includes a probe card, at least one switch and a diagnosis structure. The probe card includes a circuit board, the circuit board has a first side and a second side opposite to the first side. The at least one switch is disposed on at least one of the first side and the second side of the circuit board, wherein the at least one switch is electrically connected to the circuit board. The diagnosis structure is detachably disposed on the circuit board and electrically connected to at least one of the circuit board and the at least one switch to diagnose electrical properties of at least one of the probe card and the at least one switch.

### BACKGROUND

Testing is a key operation of semiconductor fabrication. To facilitate testing on numerous semiconductor devices (e.g., chips or dies) on a wafer at the same time, probe cards are used. A probe card includes probes that correspond to contact pads on the wafer for the semiconductor devices.

Each of the semiconductor devices has contact pads accessed for testing. To allow for more contact pads connected to the semiconductor devices, wafer level chip scale package (WLCSP) was developed. In the WLCSP technology, the semiconductor device is packaged on the wafer level. By using the WLCSPs and the probe cards, the semiconductor devices are tested more effectively with an automated test equipment (ATE). The standard number of Input/Output (IO) channels in ATE is approximately 4K, and due to the increasing interconnect density of three-dimensional Fabrics (3DFabrics) (which has exceeded 4K), the standard ATE IO channels are not sufficient to provide a viable solution for open/short circuit testing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view illustrating a semiconductor testing apparatus in accordance with some embodiments of the disclosure.

FIG. 1B is a schematic cross-sectional view illustrating a semiconductor testing apparatus in accordance with some embodiments of the disclosure.

FIG. 2 is a schematic cross-sectional view illustrating a semiconductor testing apparatus in accordance with some alternative embodiments of the disclosure.

FIG. 3A is a schematic cross-sectional view illustrating a semiconductor testing apparatus in accordance with some alternative embodiments of the disclosure.

FIG. 3B is a schematic top view illustrating an area A1 in FIG. 3A.

FIG. 4A is a schematic cross-sectional view illustrating a semiconductor testing apparatus in accordance with some alternative embodiments of the disclosure.

FIG. 4B is a schematic top view illustrating an area A2 in FIG. 4A.

FIG. 5 is a schematic cross-sectional view illustrating a semiconductor testing apparatus in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

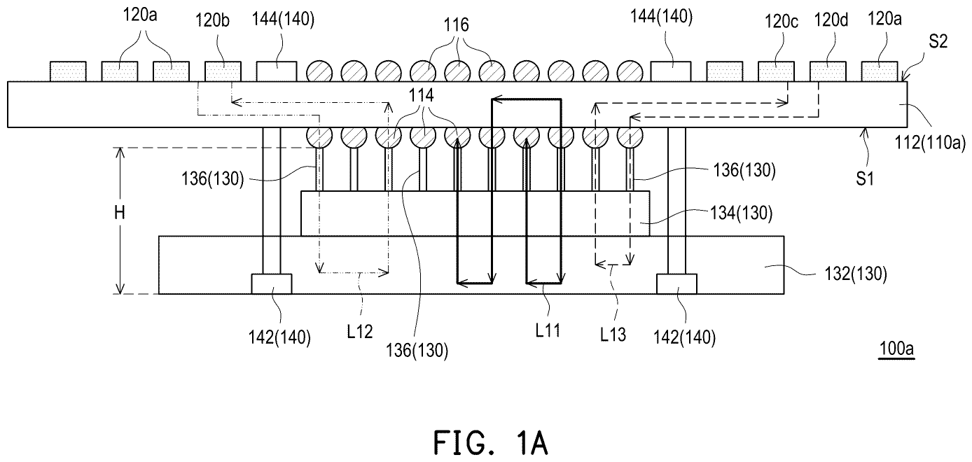

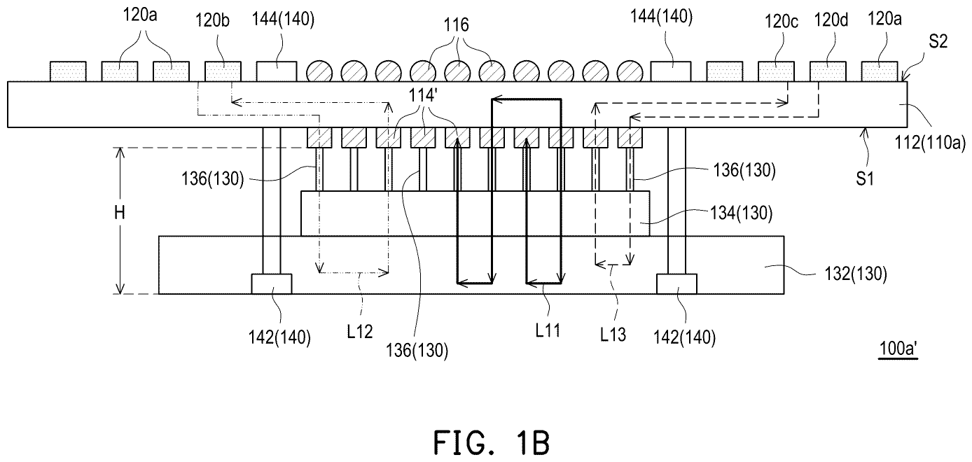

FIG. 1A is schematic cross-sectional view illustrating a semiconductor testing apparatus in accordance with some embodiments of the disclosure. Referring to FIG. 1A, a semiconductor testing apparatus 100a includes a probe card 110a, at least one switch (a plurality of switches 120a, 120b, 120c, 120d are schematically shown) and a diagnosis structure 130. The probe card 110a includes a circuit board 112, the circuit board 112 has a first side S1 and a second side S2 opposite to the first side S1. The switches 120a, 120b, 120c, 120d are disposed on the second side S2 of the circuit board 112, wherein the switches 120a, 120b, 120c, 120d are electrically connected to the circuit board 112. The diagnosis structure 130 is detachably disposed on the circuit board 112 and electrically connected to at least one of the circuit board 112 and the switches 120a, 120b, 120c, 120d to diagnose electrical properties of at least one of the probe card 110a and the switches 120a, 120b, 120c, 120d.

The circuit board 112 of the probe card 110a is configured to test the devices-under-tests (DUTs). In some embodiments, the circuit board 112 is a printed circuit board (PCB) having certain testing circuits and/or testing pads. In some other embodiments, the circuit board 112 connects the devices-under-tests (DUTs) to an automatic testing equipment (ATE) for testing. In some embodiments, the first side S1 of the circuit board 112 is adjacent to the wafer side, and the second side S2 of the circuit board 112 is adjacent to the tester side.

In the present embodiment, the circuit board 112 includes a plurality of conductive connectors 114 disposed on the first side S1. These conductive connectors 114 are arranged on the circuit board 112 at intervals. The conductive connectors 114 may be ball grid array (BGA) connectors, solder balls, metallic balls, metal pillars, controlled collapse chip connection bumps, micro bumps, electroless nickel-electroless palladium-immersion gold technique (ENEPIG) formed bumps, or the like. The conductive connectors 114 may include a conductive material such as solder, copper, aluminum, gold, nickel, silver, palladium, tin, the like, or a combination thereof. In the semiconductor testing apparatus 100a of FIG. 1A, the conductive connectors 114 are depicted as ball grid array (BGA) connectors. In the semiconductor testing apparatus 100a′ of FIG. 1B, the conductive connectors 114′ are depicted as metal pads. In some embodiments, the conductive connectors 114 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 114 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 114. The metal cap layer may include nickel, tin, tin-lead, gold, silver, palladium, indium, nickel-palladium-gold, nickel-gold, the like, or a combination thereof and may be formed by a plating process.

Alternatively, the circuit board 112 further includes a plurality of conductive connectors 116 disposed on the second side S2. These conductive connectors 116 are arranged on the circuit board 112 at intervals. In some embodiments, the conductive connectors 114 are disposed corresponded to the conductive connectors 116, respectively. The conductive connectors 116 may be ball grid array (BGA) connectors, solder balls, metallic balls, metal pillars, controlled collapse chip connection bumps, micro bumps, electroless nickel-electroless palladium-immersion gold technique (ENEPIG) formed bumps, or the like. The conductive connectors 116 may include a conductive material such as solder, copper, aluminum, gold, nickel, silver, palladium, tin, the like, or a combination thereof. In some embodiments, the conductive connectors 116 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 116 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 116. The metal cap layer may include nickel, tin, tin-lead, gold, silver, palladium, indium, nickel-palladium-gold, nickel-gold, the like, or a combination thereof and may be formed by a plating process.

The switches 120a, 120b, 120c, 120d are disposed on the second side S2 of the circuit board 112 and around the conductive connectors 116. Namely, the conductive connectors 116 are located in the central area of the circuit board 112, and the switches 120a, 120b, 120c are located in the peripheral area of the circuit board 112. In some embodiments, each of the switches 120a, 120b, 120c is a surface mount device (SMD) that is flatly attached to the second side S2 of the circuit board 112. In some embodiments, each of the switches 120a, 120b, 120c is a thin small outline package (TSOP) or thin shrink small outline package (TSSOP) that stands upright on the second side S2 of the circuit board 112, which has a smaller footprint and allows for more switches to be added. Each of the switches 120a, 120b, 120c, 120d is configured to increase the input/output (IO) channels. For example, the setting of the switches 120a, 120b, 120c, 120d can make one signal enter to produce more than one signal output, such as one input signal, producing eight output signals. When the electrical signal is input to the switch, through sequential switching, the current can flow through multiple different input/output (IO) channels to achieve signal detection. In some embodiments, a number of the switches 120a, 120b, 120c, 120d is greater than or equal to 500.

In some embodiments, each of the switches 120a, 120b, 120c, 120d is an active circuit component including one or more semiconductor devices, e.g., one or more transistors, configured to selectively couple and decouple two terminals responsive to one or more control signals received at one or more additional terminals, thereby providing a low resistance path in a switched-on state and high resistance path in a switched-off state in operation. In some embodiments, each of the switches 120a, 120b, 120c, 120d includes an n-type transistor coupled between the two terminals and having a gate configured to receive a control signal, and is thereby configured to, in operation, provide the low resistance path between the two terminals in response to the control signal having the logically high level, and provide the high resistance path between the two terminals in response to the control signal having the logically low level. In some embodiments, each of the switches 120a, 120b, 120c, 120d includes a p-type transistor coupled between the two terminals and having a gate configured to receive a control signal, and is thereby configured to, in operation, provide the low resistance path between the two terminals in response to the control signal having the logically low level, and provide the high resistance path between the two terminals in response to the control signal having the logically high level. In some embodiments, each of the switches 120a, 120b, 120c, 120d includes a transmission gate coupled between the two terminals, the transmission gate including two gates configured to receive complementary control signals, and is thereby configured to, in operation, provide the low resistance path between the two terminals in response to the control signal having a first combination of logical levels, and provide the high resistance path between the two terminals in response to the control signal having a second combination of logical levels. In some embodiments, each of the switches 120a, 120b, 120c, 120d includes is an n-type metal-oxide semiconductor (NMOS) transistor or a p-type metal-oxide semiconductor (PMOS) transistor.

Referring to FIG. 1A again, the diagnosis structure 130 is detachably disposed on the first side S1 of the circuit board 112. That is, when electrical testing of the circuit board 112 and/or the switches 120a, 120b, 120c, 120d is required, the diagnosis structure 130 can be assembled to the circuit board 112; and when the diagnosis is completed, the diagnosis structure 130 can be moved from the circuit board 112. In the present embodiment, the diagnosis structure 130 is corresponded to the conductive connectors 114 of the circuit board 112. The diagnosis structure 130 includes a switch diagnosis board 132, a pogo head 134 and a plurality of pogo pins 136. The pogo head 134 is located between the switch diagnosis board 132 and the pogo pins 136, and the pogo pins 136 are fixed to the pogo head 134 and electrically connected to the switch diagnosis board 132. In the present embodiment, the pogo pins 136 are in direct contact with the conductive connectors 114 of the circuit board 112, respectively, and the electrical signals from the switch diagnosis board 132 enter the circuit board 112 of the probe card 110a through the pogo pins 136 to diagnose electrical properties of at least one of the probe card 110a and the switches 120a, 120b, 120c, 120d. In some embodiments, a size of the diagnosis structure 130 is smaller than a size of the circuit board 112 of the probe card 110a. In some embodiments, the size of the circuit board 112 is 400 mm×400 mm. In some embodiments, a height H of the diagnosis structure 130 is less than 45 mm. In some embodiments, a size of the pogo head 134 is smaller than a size of the switch diagnosis board 132. In some embodiments, a number of the pogo pins 136 is greater than or equal to 2.

The semiconductor testing apparatus 100a in the present embodiment further includes a fixing assembly 140. The fixing assembly 140 includes a plurality of first fixing elements 142 and a plurality of second fixing elements 144. One end of the first fixing elements 142 are fixed to the switch diagnosis board 132, and the other end of the first fixing elements 142 penetrate through the circuit board 112 of the probe card 110a and are fixed to the circuit board 112 of the probe card 110a via the second fixing elements 144. In some embodiments, each of the first fixing elements 142 is screw or bolt, and each of the second fixing elements 144 is nut.

When the diagnosis structure 130 is assembled on the first side S1 of the circuit board 112, the pogo pins 136 are in direct contact with the conductive connectors 114, respectively, and the electrical signals from the switch diagnosis board 132 enter the circuit board 112 of the probe card 110a through the pogo pins 136 to form a loopback electrical path for diagnose electrical properties of at least one of the probe card 110a and the switches 120a, 120b, 120c, 120d. In the present embodiment, the loopback path L11 passing through the switch diagnosis board 132, the pogo head 134, the pogo pins 136, the conductive connectors 114 and the circuit board 112 is formed to diagnose electrical properties of the probe card 110a. The loopback path L12 passing through the switch diagnosis board 132, the pogo head 134, the pogo pins 136, the conductive connectors 114, the circuit board 112, and the switch 120b is formed to diagnose electrical properties of the switch 120b. The loopback path L13 passing through the switch diagnosis board 132, the pogo head 134, the pogo pins 136, the conductive connectors 114, the circuit board 112, the switch 120c, and the switch 120d is formed to diagnose electrical properties of the switches 120c, 120d, a cross-switch loopback is realized. In short, the diagnosis structure 130 diagnoses both the circuit board 112 and the switches 120b, 120c, 120d at the same time. In some embodiments, the diagnosis structure 130 optionally diagnoses only the circuit board 112 of the probe card 110a. In some embodiments, the diagnosis structure 130 optionally diagnoses only the switch 120b, that is, perform diagnostics on a single switch. In some embodiments, the diagnosis structure 130 optionally diagnoses only the switch 120c and switch 120d, that is, perform diagnostics on a plurality of switches.

Since the semiconductor testing apparatus 100a includes the switches 120a, 120b, 120c, 120d disposed on the circuit bord 112 of the probe card 110a and the diagnosis structure 130 is detachably disposed on the first side S1 of the circuit board 112, it is possible to achieve more than 4K input/output (IO) channels and open/short testing. In some embodiments, by the configuration described above enables the 3DFabric mechanic test chips and the interposer to perform open and short testing with automatic testing equipment (ATE) input/output (IO) channels. That is, the above configuration overcomes the limitation of the automatic testing equipment (ATE) with depreciated input/output (IO) channels that cannot be upgraded any further. In addition, the above configuration extends the automatic testing equipment (ATE) input/output (IO) channels to double or more to increase testing coverage, providing greater support for open and short testing. In addition, the semiconductor testing apparatus 100a of the present embodiment is designed to enable pre-testing and diagnosis of at least one of circuit board 112 and the switches 120a, 120b, 120c, 120d.

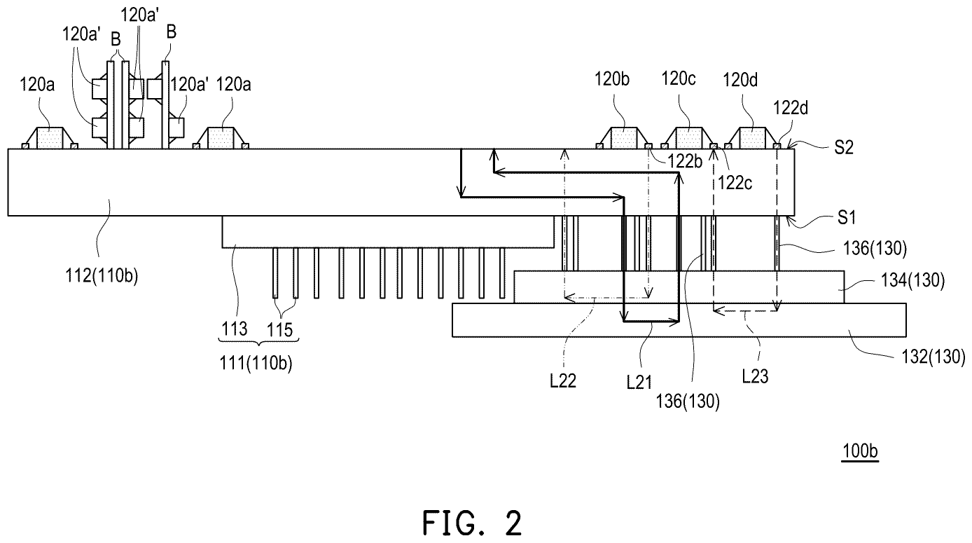

FIG. 2 is a schematic cross-sectional view illustrating a semiconductor testing apparatus in accordance with some alternative embodiments of the disclosure. Referring to FIG. 2, the semiconductor testing apparatus 100b in FIG. 2 is similar to the semiconductor testing apparatus 100a in FIG. 1A, so similar elements are denoted by the same reference numeral and the detailed description thereof is omitted herein. The difference between the semiconductor testing apparatus 100b in FIG. 2 and the semiconductor testing apparatus 100a in FIG. 1A lies in that the diagnosis structure 130 is assembled on the first side S1 of the circuit board 112 and correspond to the switches 120b, 120c, 120d. The pogo pins 136 of the diagnosis structure 130 contact to the first side S1 of the circuit board 112 of the probe card 110b.

In more detail, the probe card 110b further includes a probe module 111. The probe module 111 includes a probe head 113 and a plurality of probes 115, and the probes 115 is fixed to the probe head 113. The diagnosis structure 130 is disposed beside the probe module 111 and corresponded the switches 120b, 120c, 120d. The pogo pins 136 of the diagnosis structure 130 are in direct contact with the first side S1 of the circuit board 112, and the electrical signals from the switch diagnosis board 132 enter the circuit board 112 of the probe card 110b through the pogo pins 136 to form a loopback electrical path for diagnose electrical properties of at least one of the probe card 110b and the switches 120b, 120c, and 120d. In the present embodiment, the loopback path L21 passing through the switch diagnosis board 132, the pogo head 134, the pogo pins 136, and the circuit board 112 is formed to diagnose electrical properties of the probe card 110b. The loopback path L22 passing through the switch diagnosis board 132, the pogo head 134, the pogo pins 136, the circuit board 112, and the pad 122b of the switch 120b is formed to diagnose electrical properties of the switch 120b. The loopback path L23 passing through the switch diagnosis board 132, the pogo head 134, the pogo pins 136, the circuit board 112, the pad 122c of the switch 120c, and the pad 122d of the switch 120d is formed to diagnose electrical properties of the switches 120c, 120d, a cross-switch loopback is realized. In short, the diagnosis structure 130 diagnoses both the circuit board 112 and the switches 120b, 120c, and 120d at the same time. In some embodiments, the diagnosis structure 130 optionally diagnoses only the circuit board 112 of the probe card 110b. In some embodiments, the diagnosis structure 130 optionally diagnoses only the switch 120b, that is, perform diagnostics on a single switch. In some embodiments, the diagnosis structure 130 optionally diagnoses only the switch 120c and switch 120d, that is, perform diagnostics on a plurality of switches. In addition, each of the switches 120a, 120b, 120c, 120d is a surface mount device (SMD) that is flatly attached to the second side S2 of the circuit board 112. In some embodiments, each of the switches 120a′ is a thin small outline package (TSOP) or thin shrink small outline package (TSSOP) that stands upright on the second side S2 of the circuit board 112 through the substrate B, which can take up a smaller footprint and allows for more switches to be added.

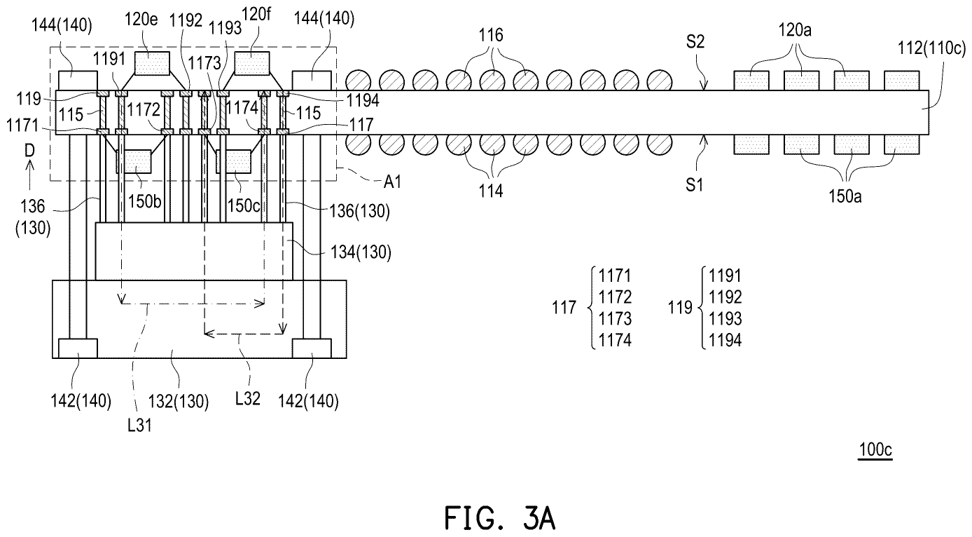

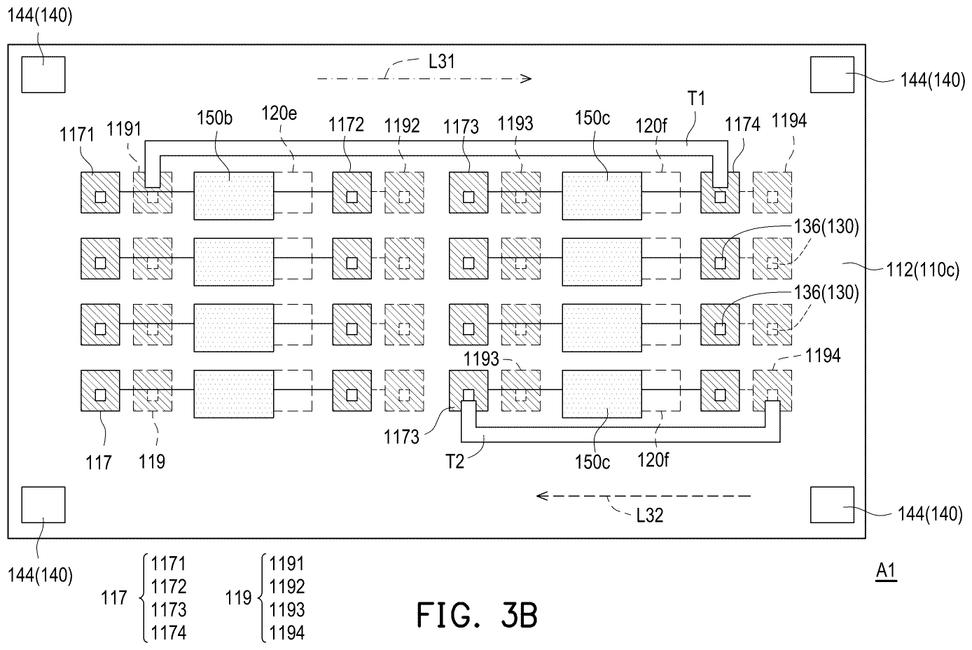

FIG. 3A is a schematic cross-sectional view illustrating a semiconductor testing apparatus in accordance with some alternative embodiments of the disclosure. FIG. 3B is a schematic top view illustrating an area A1 in FIG. 3A. It should be noted that the top view in FIG. 3B is viewed from the D direction, and some components (such as pads) are not shown for the convenience of clear explanation. Referring to FIG. 3A and FIG. 3B, the semiconductor testing apparatus 100c in FIG. 3A is similar to the semiconductor testing apparatus 100a in FIG. 1A, so similar elements are denoted by the same reference numeral and the detailed description thereof is omitted herein. The difference between the semiconductor testing apparatus 100c in FIG. 3A and the semiconductor testing apparatus 100a in FIG. 1A lies in that the semiconductor testing apparatus 100c further includes a plurality of switches 150a, 150b, 150c. The switches 150a, 150b, 150c are disposed on the first side S1 of the circuit board 112, and the diagnosis structure 130 is corresponded to the switches 150b, 150c, and the pogo pins 136 contact the circuit board 112 and the switches 150b, 150c.

In more detail, the circuit board 112 of the probe card 110c further includes a plurality of conductive vias 115, a plurality of pads 117 (including the pads 1171, 1172, 1173, 1174) and a plurality of pads 119 (including the pads 1191, 1192, 1193, 1194). The pads 117 are disposed at the first side S1, and the pads 119 are disposed at the second side S2, but not limited to. The conductive vias 115 connect the corresponding pads 117 and the corresponding pads 119, respectively. The pogo pins 136 of the diagnosis structure 130 are in direct contact with the first side S1 of the circuit board 112, and the electrical signals from the switch diagnosis board 132 enter the circuit board 112 of the probe card 110c through the pogo pins 136 to form a loopback electrical path for diagnose electrical properties of at least one of the probe card 110c and the switches 120e, 120f, 150b, and 150c. In the present embodiment, the switch 150b is electrically connected to the pad 1171 and the pad 1172 of the circuit board 112 through the wire bonding. The switch 150c is electrically connected to the pad 1173 and the pad 1174 of the circuit board 112 through the wire bonding. The switch 120e is electrically connected to the pad 1191 and the pad 1192 of the circuit board 112 through the wire bonding, for example. The switch 120f is electrically connected to the pad 1193 and the pad 1194 of the circuit board 112 through the wire bonding, for example. A trace connection T1 on the switch diagnosis board 132 connects the pad 1191 and the pad 1174. A trace connection T2 on the switch diagnosis board 132 connects the pad 1194 and the pad 1173. The loopback path L31 passing through the trace connection T1 on the switch diagnosis board 132, the pogo head 134, the pogo pins 136, the pad 1174, the conductive via 115, and the pad 1191 is formed to diagnose electrical properties of the switch 120e and the switch 150c, a double-side cross-switch loopback is realized. The loopback path L32 passing through the trace connection T2 on the switch diagnosis board 132, the pogo head 134, the pogo pins 136, the pad 1173, the conductive via 115, and the pad 1194 is formed to diagnose electrical properties of the switch 120f and the switch 150c, a double-side cross-switch loopback is realized.

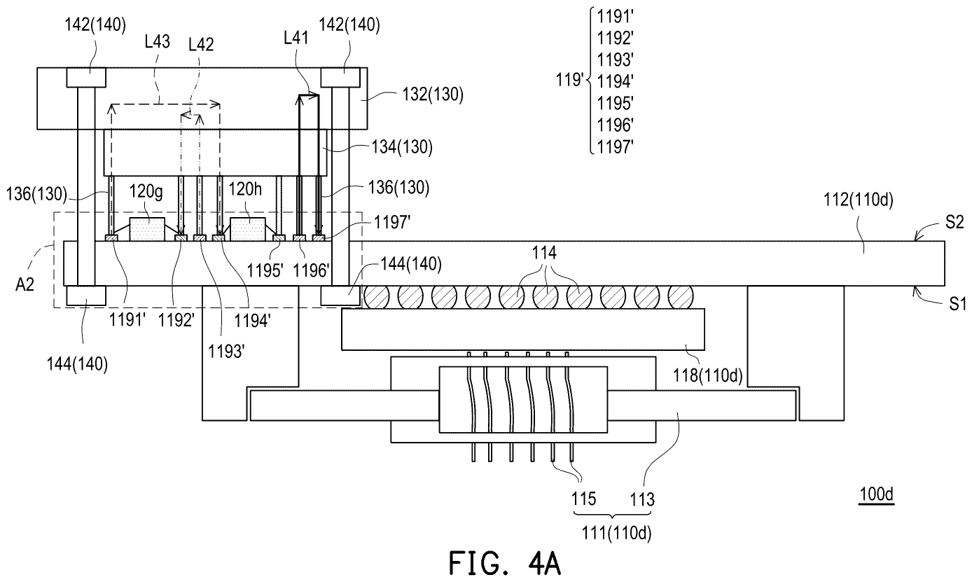

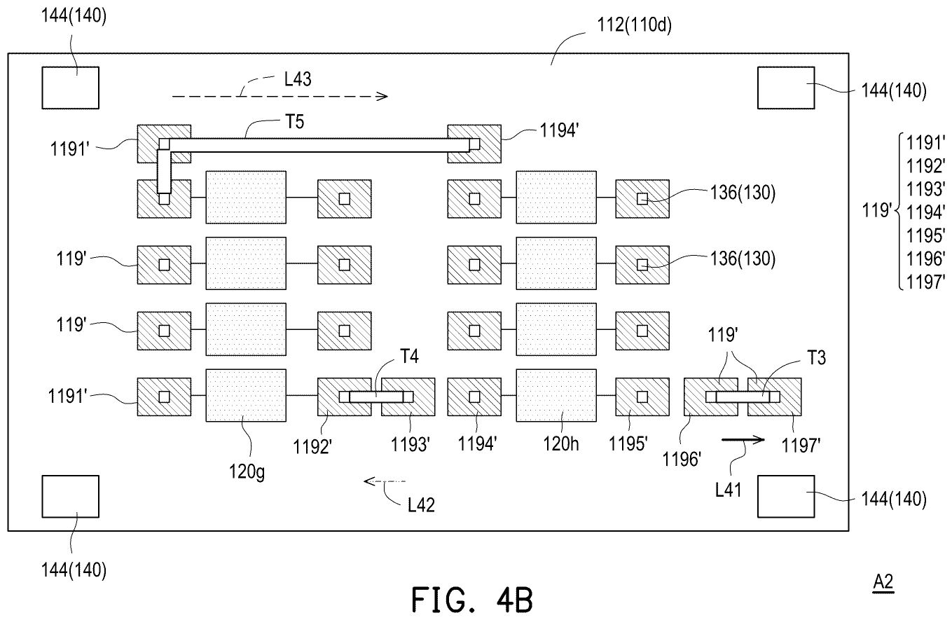

FIG. 4A is a schematic cross-sectional view illustrating a semiconductor testing apparatus in accordance with some alternative embodiments of the disclosure. FIG. 4B is a schematic top view illustrating an area A2 in FIG. 4A. Referring to FIG. 4A and FIG. 4B, the semiconductor testing apparatus 100d in FIG. 4A is similar to the semiconductor testing apparatus 100a in FIG. 1A, so similar elements are denoted by the same reference numeral and the detailed description thereof is omitted herein. The difference between the semiconductor testing apparatus 100d in FIG. 4A and the semiconductor testing apparatus 100a in FIG. 1A lies in that the diagnosis structure 130 is assembled on the second side S2 of the circuit board 112, and corresponded to the switch 120g and the switch 120h.

In more detail, the probe card 110d further includes a probe module 111 and a substrate 118 located between the circuit board 112 and the probe module 111. The probe module 111 includes a probe head 113 and a plurality of probes 115, and the probes 115 is fixed to the probe head 113. The circuit board 112 provides electrical connections to the automatic testing equipment (ATE) for testing, and the substrate 118 provides electrical connections between the circuit board 112 and the probe module 111. In some embodiments, the substrate 118 may be made as a single layer of material or from multiple layers. For example, the substrate 118 may be a multi-layer ceramic (MLC). In some embodiments, the substrate 118 may be a Multi-Layer Silicon (MLS) space transforming substrate made using silicon wafer fabrication techniques. An MLS space transforming substrate may provide finer contact pitch, as compared to an MLC space transforming substrate. In some embodiments, the substrate 118 may include, for example but is not limited to, the substrate including the contact pads, the metal lines and/or vias, but not limited to. The substrate 118 is bonded to the circuit board 112 through flip-chip bonding, with the conductive connectors 114 therebetween. In some embodiments, the substrate 118 may include other types of carriers, which may be attached to the circuit board 112 by adhesive and the contact pads may be electrically connected to the circuit board 112 by wires. An orthographic projection of the switches 120g, 120h on the circuit board 112 of the probe card 110d does not overlap with an orthographic projection of the substrate 118 on the circuit board 112. The pads 119′ (including the pads 1191′, 1192′, 1193′, 1194′, 1195′, 1196′, 1197′) of the circuit board 112 are arranged on the second side S2 at intervals.

The diagnosis structure 130 and the probe module 111 are located on opposite sides of the circuit board 112, i.e. respectively located on second side S2 and the first side S1 of the circuit board 112, and are arranged in a staggered configuration. The switch 120g is electrically connected to the pad 1191′ and the pad 1192′ of the circuit board 112 through the wire bonding. The switch 120h is electrically connected to the pad 1194′ and the pad 1195′ of the circuit board 112 through the wire bonding. A trace connection T3 on the switch diagnosis board 132 connects the pad 1196′ and the pad 1197′. A trace connection T4 on the switch diagnosis board 132 connects the pad 1193′ and the pad 1192′. A trace connection T5 on the switch diagnosis board 132 connects the pad 1191′ and the pad 1194′. The pogo pins 136 of the diagnosis structure 130 are in direct contact with the pads 119′ on the second side S2 of the circuit board 112, and the electrical signals from the switch diagnosis board 132 enter the circuit board 112 of the probe card 110d through the pogo pins 136 to form a loopback electrical path for diagnose electrical properties of at least one of the probe card 110d and the switch 120g, 120h. In the present embodiment, the loopback path L41 passing through the trace connection T3 on the switch diagnosis board 132, the pogo head 134, the pogo pins 136, the pad 1197′ and the pad 1196′ of the circuit board 112 is formed to diagnose electrical properties of the probe card 110d. The loopback path L42 passing through the trace connection T4 on the switch diagnosis board 132, the pogo head 134, the pogo pins 136, the pad 1192′ and the pad 1193′ of the circuit board 112 is formed to diagnose electrical properties of the switch 120g. The loopback path L43 passing through the trace connection T5 on the switch diagnosis board 132, the pogo head 134, the pogo pins 136, the pad 1194′ and the pads 1191′ of the circuit board 112 is formed to diagnose electrical properties of the switch 120g and the switch 120h, a cross-switch loopback is realized. In short, the diagnosis structure 130 diagnoses both the circuit board 112 and the switches 120g, 120h at the same time. In some embodiments, the diagnosis structure 130 optionally diagnoses only the circuit board 112 of the probe card 110d. In some embodiments, the diagnosis structure 130 optionally diagnoses only the switch 120g, that is, perform diagnostics on a single switch. In some embodiments, the diagnosis structure 130 optionally diagnoses only the switch 120g and switch 120h, that is, perform diagnostics on a plurality of switches.

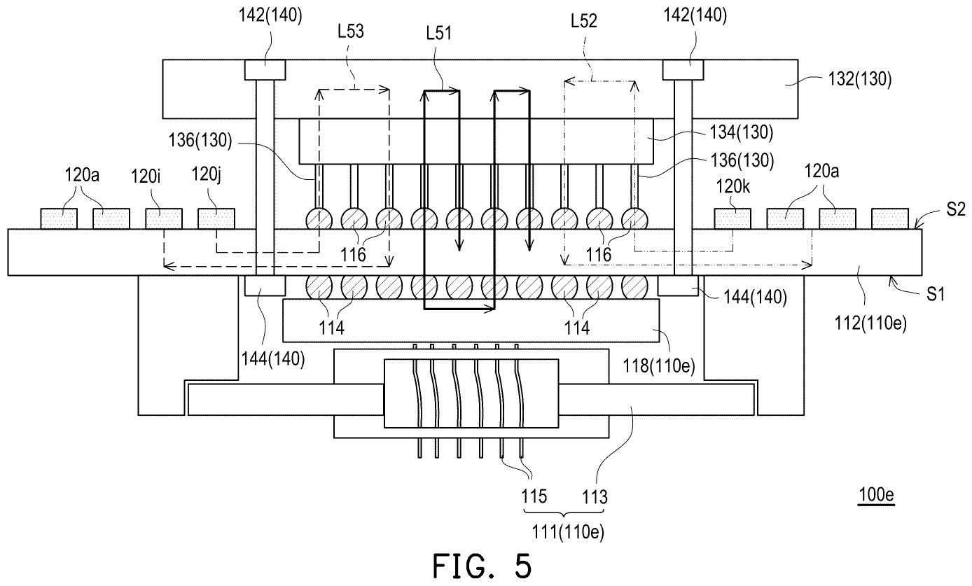

FIG. 5 is a schematic cross-sectional view illustrating a semiconductor testing apparatus in accordance with some alternative embodiments of the disclosure. Referring to FIG. 5, the semiconductor testing apparatus 100e in FIG. 5 is similar to the semiconductor testing apparatus 100a in FIG. 1A, so similar elements are denoted by the same reference numeral and the detailed description thereof is omitted herein. The difference between the semiconductor testing apparatus 100e in FIG. 5 and the semiconductor testing apparatus 100a in FIG. 1A lies in that the diagnosis structure 130 is assembled on the second side S2 of the circuit board 112, and corresponded to the conductive connectors 116.

In more detail, the probe card 110e further includes a probe module 111 and a substrate 118 located between the circuit board 112 and the probe module 111. The probe module 111 includes a probe head 113 and a plurality of probes 115, and the probes 115 is fixed to the probe head 113. The circuit board 112 provides electrical connections to the automatic testing equipment (ATE) for testing, and the substrate 118 provides electrical connections between the circuit board 112 and the probe module 111. In some embodiments, the substrate 118 may be made as a single layer of material or from multiple layers. For example, the substrate 118 may be a multi-layer ceramic (MLC). In some embodiments, the substrate 118 may be a Multi-Layer Silicon (MLS) space transforming substrate made using silicon wafer fabrication techniques. An MLS space transforming substrate may provide finer contact pitch, as compared to an MLC space transforming substrate. In some embodiments, the substrate 118 may include, for example but is not limited to, the substrate including the contact pads, the metal lines and/or vias, but not limited to. The substrate 118 is bonded to the circuit board 112 through flip-chip bonding, with the conductive connectors 114 therebetween. In some embodiments, the substrate 118 may include other types of carriers, which may be attached to the circuit board 112 by adhesive and the contact pads may be electrically connected to the circuit board 112 by wires. An orthographic projection of the switches 120a, 120i, 120j, 120k on the circuit board 112 of the probe card 110e does not overlap with an orthographic projection of the substrate 118 on the circuit board 112.

The diagnosis structure 130 and the probe module 111 are located on opposite sides of the circuit board 112, i.e. respectively located on second side S2 and the first side S1 of the circuit board 112, and are correspondingly arranged. The pogo pins 136 of the diagnosis structure 130 are in direct contact with the conductive connectors 116 of the circuit board 112, and the electrical signals from the switch diagnosis board 132 enter the circuit board 112 of the probe card 110e through the pogo pins 136 to form a loopback electrical path for diagnose electrical properties of at least one of the probe card 110e and the switches 120i, 120j, and 120k. In the present embodiment, the loopback path L51 passing through the switch diagnosis board 132, the pogo head 134, the pogo pins 136, the conductive connectors 116, the circuit board 112, and the conductive connectors 114 is formed to diagnose electrical properties of the probe card 110e. The loopback path L52 passing through the switch diagnosis board 132, the pogo head 134, the pogo pins 136, the conductive connectors 116, the circuit board 112, and the switch 120k is formed to diagnose electrical properties of the switch 120k. The loopback path L53 passing through the switch diagnosis board 132, the pogo head 134, the pogo pins 136, the conductive connectors 116, the circuit board 112, the switch 120i, and the switch 120j is formed to diagnose electrical properties of the switches 120i, 120j, a cross-switch loopback is realized. In short, the diagnosis structure 130 diagnoses both the circuit board 112 and the switches 120i, 120j, and 120k at the same time. In some embodiments, the diagnosis structure 130 optionally diagnoses only the circuit board 112 of the probe card 110e. In some embodiments, the diagnosis structure 130 optionally diagnoses only the switch 120k, that is, perform diagnostics on a single switch. In some embodiments, the diagnosis structure 130 optionally diagnoses only the switch 120i and switch 120j, that is, perform diagnostics on a plurality of switches.

When electrical testing of the circuit board 112 and/or the switches 120i, 120j, 120k is required, the diagnosis structure 130 can be assembled to the circuit board 112; and when the diagnosis is completed, the diagnosis structure 130 can be moved from the circuit board 112. After removing the diagnosis structure 130, wafer testing can be performed. Namely, at least one the circuit board 112 of probe card 110e and the switches 120i, 120j, 120k can be pre-tested, diagnosed and maintained before testing on the devices-under-tests (DUTs). When the wafer test is performed, the probes 115 of the probe card 110e are first aligned with the testing pads on the wafer respectively, and then the probe card 110e is vertically descended or the wafer holder is vertically ascended until the probes 115 contact the testing pads. Meanwhile, the probe card 110e transmits input signals to the devices-under-tests (DUTs) and then receives output signals outputted from the devices-under-tests (DUTs), in which the output signals are in response to the input signals, and the input signals inputted to the probe card 110e and the devices-under-tests (DUTs) are generated by the tester. Thereafter, the probe card 110e transmits the output signals to the tester, and the tester analyzes the output signals to determine the electrical properties of the devices-under-tests (DUTs).

In short, during testing, the probe card is provided with the at least one switch to increase IO channels. And then, the detachably diagnosis structure is placed on the probe card to test the at least one switch, wherein the diagnosis structure is placed in different locations, such as the front or back side of the probe card depending on the testing setup. And then, the diagnosis structure is used to check if the at least one switch is functioning correctly before testing, and removed the diagnosis structure once confirmed operational. Finally, the devices-under-tests (DUTs) is tested by using the probe card with the at least one switch.

According to some embodiments, a semiconductor testing apparatus includes a probe card, at least one switch and a diagnosis structure. The probe card includes a circuit board, the circuit board has a first side and a second side opposite to the first side. The at least one switch is disposed on at least one of the first side and the second side of the circuit board, wherein the at least one switch is electrically connected to the circuit board. The diagnosis structure is detachably disposed on the circuit board and electrically connected to at least one of the circuit board and the at least one switch to diagnose electrical properties of at least one of the probe card and the at least one switch.

According to some embodiments, a semiconductor testing apparatus includes a probe card, at least one switch and a diagnosis structure. The probe card includes a circuit board, a probe module and a substrate located between the circuit board and the probe module. The circuit board has a first side and a second side opposite to the first side. The at least one switch is disposed on at least one of the first side and the second side of the circuit board, wherein the at least one switch is electrically connected to the circuit board, and an orthographic projection of the least one switch on the circuit board does not overlap with an orthographic projection of the substrate on the circuit board. The diagnosis structure is detachably disposed on the circuit board and electrically connected to at least one of the circuit board and the at least one switch to diagnose electrical properties of at least one of the probe card and the at least one switch.

According to some embodiments, a semiconductor testing method including providing a probe card, the probe card comprising a circuit board, and the circuit board having a first side and a second side opposite to the first side; assembling at least one switch on at least one of the first side and the second side of the circuit board, wherein the at least one switch is electrically connected to the circuit board; and disposing a diagnosis structure on the circuit board of the probe card and electrically connected to at least one of the circuit board and the at least one switch to diagnose electrical properties of at least one of the probe card and the at least one switch.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor testing apparatus, comprising:
a probe card comprising a circuit board, the circuit board having a first side and a second side opposite to the first side;
at least one switch disposed on at least one of the first side and the second side of the circuit board, wherein the at least one switch is electrically connected to the circuit board; and
a diagnosis structure detachably disposed on the circuit board and electrically connected to at least one of the circuit board and the at least one switch to diagnose electrical properties of at least one of the probe card and the at least one switch.

2. The semiconductor testing apparatus of claim 1, wherein the diagnosis structure comprises a switch diagnosis board, a pogo head and a plurality of pogo pins, the pogo head is located between the switch diagnosis board and the plurality of pogo pins, and the plurality of pogo pins are fixed to the pogo head and electrically connected to the switch diagnosis board.

3. The semiconductor testing apparatus of claim 2, wherein the diagnosis structure is detachably disposed on the first side of the circuit board.

4. The semiconductor testing apparatus of claim 3, wherein the circuit board comprises a plurality of first conductive connectors disposed on the first side, the diagnosis structure is corresponded to the first conductive connectors, and the plurality of pogo pins contact the plurality of first conductive connectors.

5. The semiconductor testing apparatus of claim 4, wherein the at least one switch is a plurality of switches, the plurality of switches is disposed on the second side of the circuit board, the circuit board comprises a plurality of second conductive connectors disposed on the second side, and the plurality of switches are disposed around the second conductive connectors.

6. The semiconductor testing apparatus of claim 3, wherein the at least one switch comprises a plurality of first switches, the plurality of first switches is disposed on the second side of the circuit board, the diagnosis structure is corresponded to the plurality of first switches, and the plurality of pogo pins contact to the circuit board.

7. The semiconductor testing apparatus of claim 6, wherein the at least one switch further comprises a plurality of second switches, the plurality of second switches is disposed on the first side of the circuit board, the diagnosis structure is corresponded to the plurality of second switches, and the plurality of pogo pins contact the circuit board and the plurality of second switches.

8. The semiconductor testing apparatus of claim 2, wherein the diagnosis structure is detachably disposed on the second side of the circuit board.

9. The semiconductor testing apparatus of claim 8, wherein the circuit board comprises a plurality of first conductive connectors disposed on the first side and a plurality of second conductive connectors disposed on the second side, the diagnosis structure is corresponded to the second conductive connectors, and the plurality of pogo pins contact the plurality of second conductive connectors.

10. The semiconductor testing apparatus of claim 9, wherein the at least one switch is a plurality of switches, the plurality of switches is disposed on the second side of the circuit board, and the plurality of switches are disposed around the second conductive connectors.

11. The semiconductor testing apparatus of claim 8, wherein the at least one switch is a plurality of switches, the plurality of switches is disposed on the second side of the circuit board, the diagnosis structure is corresponded to the plurality of switches, and the plurality of pogo pins contact the circuit board and the plurality of switches.

12. A semiconductor testing apparatus, comprising:
a probe card comprising a circuit board, a probe module and a substrate located between the circuit board and the probe module, the circuit board having a first side and a second side opposite to the first side;
at least one switch disposed on at least one of the first side and the second side of the circuit board, wherein the at least one switch is electrically connected to the circuit board, and an orthographic projection of the least one switch on the circuit board does not overlap with an orthographic projection of the substrate on the circuit board; and
a diagnosis structure detachably disposed on the circuit board and electrically connected to at least one of the circuit board and the at least one switch to diagnose electrical properties of at least one of the probe card and the at least one switch.

13. The semiconductor testing apparatus of claim 12, wherein a size of the diagnosis structure is smaller than a size of the probe card.

14. The semiconductor testing apparatus of claim 12, wherein a height of the diagnosis structure is less than 45 mm.

15. The semiconductor testing apparatus of claim 12, wherein the diagnosis structure comprises a switch diagnosis board, a pogo head and a plurality of pogo pins, the pogo head is located between the switch diagnosis board and the plurality of pogo pins, and the plurality of pogo pins are fixed to the pogo head and electrically connected to the switch diagnosis board.

16. The semiconductor testing apparatus of claim 15, wherein a number of the plurality of pogo pins is greater than or equal to 2.

17. The semiconductor testing apparatus of claim 12, wherein the probe module comprises a probe head and a plurality of probes, and the plurality of probes is fixed to the probe head.

18. A semiconductor testing method, comprising:
providing a probe card, the probe card comprising a circuit board, and the circuit board having a first side and a second side opposite to the first side;
assembling at least one switch on at least one of the first side and the second side of the circuit board, wherein the at least one switch is electrically connected to the circuit board; and
disposing a diagnosis structure on the circuit board of the probe card and electrically connected to at least one of the circuit board and the at least one switch to diagnose electrical properties of at least one of the probe card and the at least one switch.

19. The semiconductor testing method of claim 18, wherein the diagnosis structure comprises a switch diagnosis board, a pogo head and a plurality of pogo pins, the pogo head is located between the switch diagnosis board and the plurality of pogo pins, and the plurality of pogo pins are fixed to the pogo head and electrically connected to the switch diagnosis board.

20. The semiconductor testing method of claim 18, wherein the at least one switch is flatly attached to the second side of the circuit board or stands upright on the second side of the circuit board through a substrate.
